(19) United States
(12) Patent Application Publication
(10) Pub. No.: US 2016/0053984 A1
(43) Pub. Date: Feb. 25, 2016

(54) APPARATUS FOR DIRECT LED UV IRRADIATION

(71) Applicants: MICHAEL D. CALLAGHAN, Minneapolis, MN (US); Robert L. Sargent, Chelmsford, MA (US)

(72) Inventors: MICHAEL D. CALLAGHAN, Minneapolis, MN (US); Robert L. Sargent, Chelmsford, MA (US)

(21) Appl. No.: 14/830,972

(22) Filed: Aug. 20, 2015

Related U.S. Application Data
(60) Provisional application No. 62/040,226, filed on Aug. 21, 2014.

(51) Int. Cl. F21V 29/74; B05D 3/06; F21K 99/00; H01L 25/075; F21V 23/06

(52) U.S. Cl. CPC F21V 29/74; H01L 25/0753; F21V 23/06; F21K 9/90; B05D 3/067; F21Y 2101/02

(57) ABSTRACT

An apparatus for direct LED irradiation, such as using UV, has a LED package with a plurality of individual LED units, the LED package attached to a heat sink. The heat sink transmits heat from the LED units to a coolant, which is circulated away from the LEDs during use. Radiation emitted from the LED package passes through a gap defined by a housing structure enclosing the LED package and heat sink.

### CROSS-REFERENCES TO RELATED APPLICATIONS

This application claims priority under 35 U.S.C. §119 (e) to, and hereby incorporates by reference, U.S. Provisional Application No. 62/040,226, filed 21 Aug. 2014.

### BACKGROUND OF THE INVENTION

1. Field of the Invention

This invention relates to curing printed substrates and, in particular, this invention relates to curing UV-sensitive inks printed onto a substrate.

2. Background

Currently, UV-sensitive ink is printed onto a substrate, then subjected to UV irradiation to cure the ink and thereby prevent distortion during the remainder of the printing operation. While enabling a more efficient means of generating radiation, light emitting diodes (LEDs) nonetheless generate considerable amounts of heat during use. This generated heat must be efficiently and effectively removed from the LEDs to prevent degradation of the LEDs and warping and distortion of the printed product

### SUMMARY

This invention substantially meets the aforementioned needs of the industry by providing an apparatus for direct LED UV irradiation, which efficiently and effectively removes LED-generated heat. The apparatus may include a plurality of LEDs (array) generating electromagnetic energy, such as for curing printed ink on a substrate. The LEDs may be mounted to a heat sink, which may cool the LEDs. A side cover or light guide may be present. As a light guide, the side cover may direct a light beam onto a surface such as a substrate to be cured. Such directed beam may be a two-dimensional, substantially uniform flood of radiation onto the substrate surface. The present apparatus may include a modular, electrical interconnect apparatus. The present device may be shortened or lengthened by deleting or adding LEDs and by shortening or lengthening the remainder of the cover and heat sink.

Accordingly, there is provided an apparatus for generating and directing electromagnetic energy onto a substrate, the apparatus comprising a heat sink, a LED array with a plurality of LED units attached to the heat sink such that the heat sink and LED array are disposed within a housing and in which electrical power is supplied to the LED units and coolant is provided to circulate within the heat sink when electromagnetic energy is being directed onto the substrate.

There is also provided a method of manufacturing an apparatus for generating and directing electromagnetic energy onto a substrate, the method including enclosing a heat sink attached to a LED array within a housing, the LED array having a plurality of LED units and attached to the heat sink such that electrical power is supplied to the LED units and such that coolant is circulated in the heat sink when electromagnetic energy is being directed onto the substrate.

There is still yet provided a method of curing ink printed on a substrate, the method including providing electrical power to a LED array, the LED array attached to a heat sink and enclosed within a housing, the LED array, heat sink, and housing attached to a printing press, the heat sink circulating a coolant to maintain the LED array within a, e.g., desired, temperature range.

These and other objects, features, and advantages of this invention will become apparent from the description which follows, when considered in view of the accompanying drawings.

### BRIEF DESCRIPTION OF THE DRAWINGS

FIG. 1 is a one embodiment of the apparatus for direct LED radiation of this invention.

FIG. 2 is a transverse cross section of the apparatus of FIG. 1.

FIG. 3 is a longitudinal cross-section of the apparatus of FIG. 1.

It is understood that the above-described figures are only illustrative of the present invention and are not contemplated to limit the scope thereof.

### DETAILED DESCRIPTION

Any references to such relative terms as underside, or the like, are intended for convenience of description and are not intended to limit the present invention or its components to any one positional or spatial orientation. All dimensions of the components in the attached figures may vary with a potential design and the intended use of an embodiment of the invention without departing from the scope of the invention.

Each of the additional features and methods disclosed herein may be utilized separately or in conjunction with other features and methods to provide improved devices of this invention and methods for making and using the same. The detailed description disclosed herei006E is merely intended to teach a person of skill in the art further details for practicing preferred aspects of the present teachings and is not intended to limit the scope of the invention. Therefore, specific combinations of features and methods disclosed in the following detailed description may not be necessary to practice the invention in the broadest sense, and are instead taught merely to particularly describe representative and preferred embodiments of the invention.

A person of ordinary skill in the art will readily appreciate that individual components shown on various embodiments of the present invention are interchangeable to some extent and may be added or interchanged on other embodiments without departing from the spirit and scope of this invention.

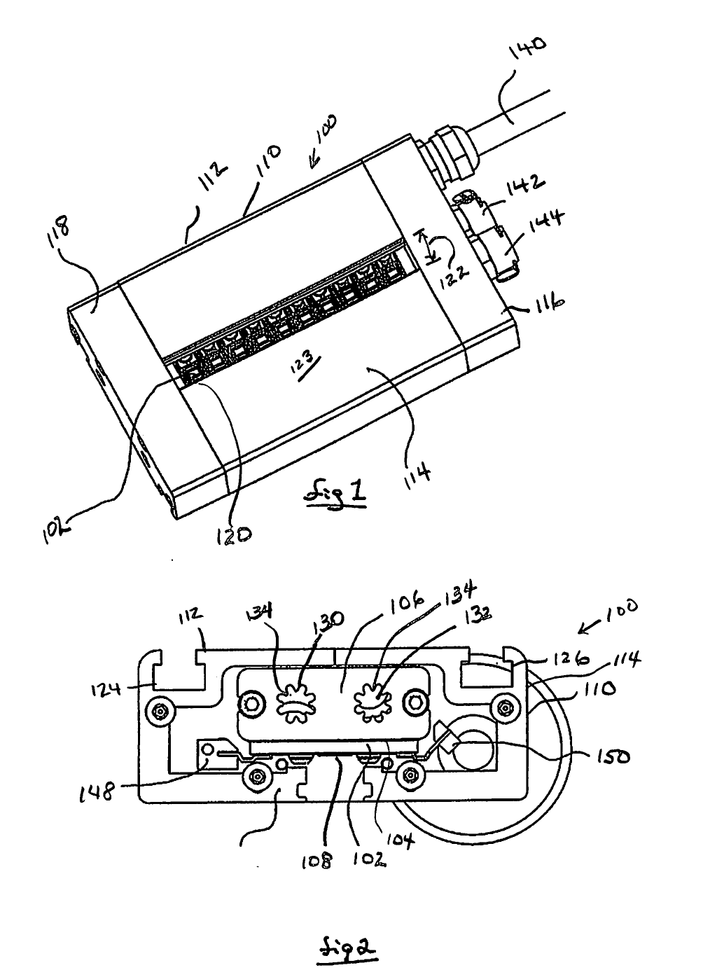

One embodiment of the apparatus for direct LED UV irradiation of this invention is shown in the figures at 100 and includes an LED array or package 102 attached, in this case, to the underside 104 of a heat sink 106. The LED package 102 may include one or more individual LEDs (units) 108 to generate and emit the desired radiation. The LED package 102 and heat sink 106 are disposed within a housing 110. The housing 110, in turn, may include one or more side covers, such as 112, 114, a connection cap 116, and a water return or end cap 118. As best seen in FIG. 1, a gap or opening 120 is defined between an underside 123 of the side covers 112, 114. In the embodiment shown, irradiation emitted from the LED units 108 passes through the gap 120 to impinge a substrate and, for example, cure a UV-sensitive ink printed on the substrate.

In the embodiment shown, a width 122 of the gap 120 may be adjusted to accommodate a desired image size. This adjustment may occur during manufacturing and be a permanent feature or a person of ordinary skill in the art will readily create structure for adjusting the magnitude of the gap width 122 to create a desired image size during use of the instant device. A lens may be present to cover the gap 120, the lens allowing any desired variation of electromagnetic wavelengths to pass therethrough. Mounting slots 124, 126 are defined in the respective side covers 112, 114.

A plurality, for example two, fluid pathways 130, 132 may be defined, e.g., longitudinally, in the heat sink 106. One or both pathway 130, 132 may include cooling fins 134 to increase the surface area exposed to the fluid circulating therein, thereby maximizing heat transfer from the heat sink 106 into the fluid being circulated. Exemplary cooling fins are described in abandoned U.S. patent application Ser. No. 12/177,624, hereby incorporated by reference.

The connection cap 116, in the embodiment depicted, has, or is attachable to, an electrical power connection 140, and respective ingress and egress fluid coolant (e.g., water) connections 142, 144. The electrical power connection 140 includes conductors for providing electrical power to the LED units 108, as well as other electrically-operated features. The ingress and egress connections 142, 144 provide fluid to, and accept fluid from, the fluid pathways 130, 132. For example, the ingress connector 142 may provide coolant to the fluid pathway 132 and the egress connector 144 may accept coolant from the fluid pathway 134. Defined within the water return/end cap 118 is a fluid pathway (not shown) accepting coolant from one of the pathways 130, 132 and delivering the accepted coolant to the other of the pathways 132, 130.

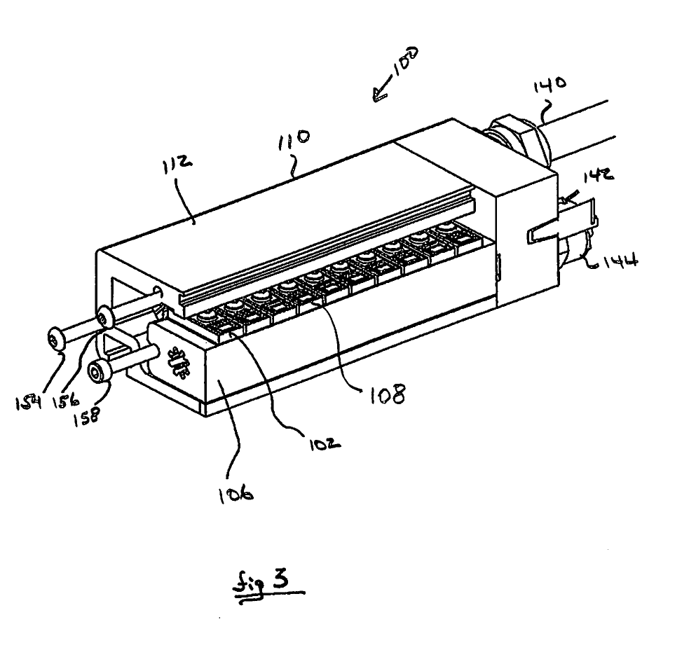

As best seen in FIG. 2, electrical tab connectors 148, 150 may extend from individual LED units 108. For example, adjacent electrical tabs 148, 150 may be opposite in polarity, so as to be connected in series. Alternatively, connectors such as those disclosed and described in abandoned U. S. patent application Ser. No. 14/809,176, hereby incorporated by reference, may be used in place of the electrical tab connectors 148, 150.

The present apparatus is installed, for example, on a printing press using UV-activated inks, by sliding the device so as to dispose a rail (not shown) in each of the mounting slots 124, 126. Then is secured in place using mounting screws 154, 156, 158, or by other means. The LED package 102 is energized when desired, to emit radiation, such as UV spectra electromagnetic radiation with any desired peak or peaks.

If so equipped, the gap width 122 of the opening 120 is adjusted to produce the desired image size for a specific application. External pumps (not shown) may be present to provide coolant to be circulated, such as by means of the ingress and egress fluid connections 142, 144, to supply and accept fluid to and from the fluid pathways 130, 132, to thereby maintain the LED package 102 at a desired, operable temperature range.

The heat sink 106 may be made from any suitable temperature-conducting material, such as, without limitation, extruded aluminum or copper or heat-conducting polymers known to a person of ordinary skill in the art. Suitable and nonlimiting LEDs include Nichia NCSU276A and SemiLEDs EV-U80T-U.

The device of this invention may be shortened or lengthened by deleting or adding LEDs and shortening or lengthening the remainder of the cover and heat sink. The curing surface may be any distance desired, such as, 5 mm to 200 mm. If present, the glass cover, lens or other optic would both protect the individual LED units 108, other electrical and functional features, and provide other desired optical characteristics.

Because numerous modifications of this invention may be made without departing from the spirit thereof, the scope of the invention is not to be limited to the embodiments illustrated and described. Rather, the scope of the invention is to be determined by the appended claims and their equivalents.

What is claimed is:

1. An apparatus for generating and directing electromagnetic energy onto a substrate, comprising:
a heat sink;
a LED array having a plurality of LED units, attached to said heat sink;
said heat sink and said LED array disposed within a housing such that electrical power is supplied to said LED units and such that coolant is circulated in said heat sink when electromagnetic energy emitted from said LED array is directed on said substrate.

2. The apparatus of claim 1, wherein a plurality of fluid pathways are defined in said heat sink.

3. The apparatus of claim 2, wherein coolant is circulated within said fluid pathways.

4. The apparatus of claim 2, wherein one of said fluid pathways defines cooling fins.

5. The apparatus of claim 1, wherein said LED units includes a pair of electrical tab connectors to connecting adjacent tab connectors of opposite electrical polarities.

6. The apparatus of claim 1, wherein said housing includes one or more side cover, a connection cap and an end cap.

7. The apparatus of claim 6, wherein, electrical power is supplied to said LED array by said connection cap.

8. The apparatus of claim 6, wherein said connection cap includes an electrical power connection, an ingress connection and an egress connection, wherein electrical power is supplied to said LED array from said electrical power connection, and wherein coolant is provided to, and accepted from, said heat sink by said ingress connection and said egress connection.

9. The apparatus of claim 6, wherein a gap is defined within said one or more side cover such that electromagnetic radiation emitted from said LED units and directed onto said substrate passes through said gap.

10. The apparatus of claim 9, wherein said gap is dimensioned to provide an image size so as to direct said radiation onto substrate in a desired pattern.

11. A method of manufacturing an apparatus for generating and directing electromagnetic energy onto a substrate, the method comprising enclosing a heat sink attached to a LED array within a housing, said LED array having a plurality of LED units and attached to said heat sink, such that electrical power is supplied to said LED units and such that coolant is circulated in said heat sink when electromagnetic energy is being directed onto said substrate.

12. The method of claim 11, wherein said enclosed heat sink defines a plurality of fluid pathways, coolant circulated within said fluid pathways.

13. The method of claim 12, wherein one of said fluid pathways defines cooling fins.

14. The method of claim 11, wherein each of said LED units includes a pair of electrical tab connectors, each electrical tab connector electrically connected to an opposite polarity of said LED unit, and comprising electrically connecting adjacent electrical tab connectors of opposite polarities in series.

15. The method of claim 11, wherein said housing defines a gap, electromagnetic energy generated by said LED array passing through said gap and onto said substrate.

16. A method of curing an ink printed on a substrate, comprising providing electrical power to a LED array, said LED array attached to a heat sink and enclosed within a housing, said LED array, said heat sink, and said housing attached to a printing press, said heat sink circulating a coolant to remove heat from said LED array.

17. The method of claim 16, wherein coolant is circulated within a pair of fluid pathways defined in said heat sink.

18. The method of claim 16, wherein UV light generated by said LED array passes through a gap defined in said housing and onto said substrate.

19. The method of claim 18, wherein said gap is dimensioned to create an image size onto said substrate.

20. The method of claim 16, further comprising circulating coolant to remove heat from said LED array into said heat sink and to transmit said removed heat into said circulating coolant.
